(19) United States
(12) Patent Application Publication
(10) Pub. No.: US 2016/0140685 A1
(43) Pub. Date: May 19, 2016

(54) DISPLAY INCLUDING SENSORS

(71) Applicant: Pixtronix, Inc., San Diego, CA (US)

(72) Inventors: Xia Ren, Tempe, AZ (US); Gianni Taraschi, Arlington, MA (US)

(21) Appl. No.: 14/543,655

(22) Filed: Nov. 17, 2014

(51) Int. Cl. G06T 1/20; B81C 1/00; B81B 7/00; G09G 5/36; G02B 26/02

(52) U.S. Cl. CPC G06T 1/20; G09G 5/363; G02B 26/02; B81B 7/0038; B81C 1/00285; G09G 2300/0408

(57) ABSTRACT

This disclosure provides devices, systems and methods for providing MEMS display elements in a display region and MEMS sensors in a shelf region. In one aspect, a display device includes a first substrate with a display region and a shelf region extending from the display region, and a second substrate over the display region and a portion of the shelf region. MEMS display elements can be in the display region and MEMS sensors can be in the covered portion of the shelf region. In some implementations, the MEMS sensors are formed simultaneously as the MEMS display elements. In some implementations, the MEMS sensors share at least two or more thin film layers with the MEMS display elements. In some implementations, the MEMS sensors are sealed by a hermetic seal and the MEMS display elements are sealed by a non-hermetic seal.

### TECHNICAL FIELD

This disclosure relates to packaging of a display device, and more particularly to providing MEMS devices in addition to MEMS display elements in unused shelf regions of the display device.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography and/or other micromachining processes that etch away parts of substrates and/or deposited material layers, or that add layers to form electrical and electromechanical devices.

### SUMMARY

The systems, methods and devices of this disclosure each have several innovative aspects, no single one of which is solely responsible for the desirable attributes disclosed herein.

One innovative aspect of the subject matter described in this disclosure can be implemented in a display device including a first substrate having a display region and a shelf region. The display device also includes a plurality of MEMS display elements in the display region, where each of the display elements includes two or more thin film layers, one or more MEMS devices in the shelf region where each of the MEMS devices include the same two or more thin film layers, a second substrate over the plurality of MEMS display elements in the display region and over the one or more MEMS devices in the shelf region, a first seal around the MEMS display elements in the display region and between the first substrate and the second substrate, and a second seal around the MEMS devices in the shelf region and between the first substrate and the second substrate where the second seal is different than the first seal.

In some implementations, the display device further includes an IC in a portion of the shelf region exposed by the second substrate. In some implementations, the MEMS display elements include shutter-based display elements. In some implementations, the second substrate has a transparent region and a non-transparent region, the transparent region over the MEMS display elements in the display region and the non-transparent region over the one or more MEMS devices in the shelf region. In some implementations, the one or more MEMS devices include one or more MEMS sensors. In some implementations, the first seal is a non-hermetic seal and the second seal is a hermetic seal. In some implementations, the two or more thin film layers of the MEMS display elements share the same composition and thickness as the two or more thin film layers of the one or more MEMS devices.

Another innovative aspect of the subject matter described in this disclosure can be implemented in a display device including a first substrate having a display region and a shelf region and means for displaying an image in the display region, the displaying means including two or more thin film layers and including a laterally-movable structure configured to control transmission of light in the display device. The display device further includes means for sensing in the shelf region, the sensing means including the same two or more thin film layers. The display device further includes a second substrate over the displaying means in the display region and over the sensing means in the shelf region, first means for sealing around the displaying means in the display region and between the first substrate and the second substrate, and second means for sealing around the sensing means in the shelf region and between the first substrate and the second substrate, where the second sealing means is different than the first sealing means.

In some implementations, the display device further includes an IC in a portion of the shelf region exposed by the second substrate. In some implementations, the displaying means include shutter-based MEMS light modulators. In some implementations, the first sealing means is non-hermetic and the second sealing means is hermetic.

Another innovative aspect of the subject matter described in this disclosure can be implemented in a method of manufacturing a display device. The method includes providing a first substrate having a display region and a shelf region, forming in the display region a plurality of MEMS display elements in one or more thin film processing steps, forming in the shelf region one or more MEMS devices using at least a subset of the one or more thin film processing steps, providing a second substrate over the plurality of MEMS display elements in the display region and over the one or more MEMS devices in the shelf region, forming a first seal around the MEMS display elements in the display region and between the first substrate and the second substrate, and forming a second seal around the one or more MEMS devices in the shelf region and between the first substrate and the second substrate, where the second seal is different than the first seal.

In some implementations, the method further includes bonding an IC to a portion of the shelf region exposed by the second substrate. In some implementations, the MEMS display elements include shutter-based display elements. In some implementations, the one or more MEMS devices include one or more MEMS sensors. In some implementations, the first seal is a non-hermetic seal and the second seal is a hermetic seal. In some implementations, forming the one or more MEMS devices in the shelf region occurs simultaneously with forming the plurality of MEMS display elements in the display region.

Details of one or more implementations of the subject matter described in this disclosure are set forth in the accompanying drawings and the description below. Other features, aspects and advantages will become apparent from the description, the drawings and the claims. Note that the relative dimensions of the following figures may not be drawn to scale.

### BRIEF DESCRIPTION OF THE DRAWINGS

FIG. 1A shows a schematic diagram of an example direct-view microelectromechanical systems (MEMS)-based display apparatus.

FIG. 1B shows a block diagram of an example host device.

FIGS. 2A and 2B show views of an example dual actuator shutter assembly.

FIG. 3A shows a top view of an example display device indicating unused areas of a substrate.

FIG. 3B shows a cross-sectional side view of the example display device taken along line X-X in FIG. 3A.

FIG. 4 shows a perspective view of an example display device including a second substrate extending over sensor regions of the display device.

FIG. 5 shows a top view of an example display device including a second substrate with arms extending over two sides of the display device.

FIG. 6 shows a top view of an example display device with a display region sealed by a non-hermetic seal and sensor regions sealed by a hermetic seal.

FIG. 7 shows a cross-sectional view of an example MEMS display element and MEMS device on a substrate.

FIG. 8 shows a flow diagram illustrating an example process for manufacturing a display device.

FIGS. 9A and 9B show system block diagrams of an example display device that includes a plurality of display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that is capable of displaying an image, whether in motion (such as video) or stationary (such as still images), and whether textual, graphical or pictorial. The concepts and examples provided in this disclosure may be applicable to a variety of displays, such as liquid crystal displays (LCDs), organic light-emitting diode (OLED) displays, field emission displays, and electromechanical systems (EMS) and microelectromechanical (MEMS)-based displays, in addition to displays incorporating features from one or more display technologies.

The described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, wearable devices, clocks, calculators, television monitors, flat panel displays, electronic reading devices (such as e-readers), computer monitors, auto displays (such as odometer and speedometer displays), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, in addition to non-EMS applications), aesthetic structures (such as display of images on a piece of jewelry or clothing) and a variety of EMS devices.

The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

A display device can be packaged to have two substrates coupled or otherwise attached to one another. One or both of the substrates can be transparent to display an image. TFTs and display elements can be disposed on a first substrate and covered by a second substrate. While the second substrate can cover the first substrate in a region through which the image is displayed, some region(s) of the first substrate may not be covered by the second substrate. To permit room for an IC, a portion of the first substrate is left uncovered for IC bonding. The IC is to be bonded on a shelf or ledge of the first substrate, where the ledge or shelf region extends from one or more sides of the first substrate. A portion of the second substrate can be removed (such as cut off and thrown away) to permit the IC to be bonded to the shelf or ledge of the first substrate. Additional device components, such as display elements and TFTs, are either not formed on the shelf or otherwise removed to leave room for IC bonding as a result. This can lead to unused spaces in the display device and a waste of processed materials.

In some implementations, a display device can include two different-sized substrates, a larger substrate having a display region and a shelf region, and a smaller substrate over the display region and a portion of the shelf region. MEMS display elements can be formed, placed or positioned in, or on the display region and MEMS devices, such as MEMS sensors, can be formed, placed or positioned in, or on the portion of the shelf region covered by the smaller substrate. An integrated circuit (IC) can be attached to another portion of the shelf region. The MEMS display elements and the MEMS devices can be formed at the same time using one or more of the same thin film processing steps. In some implementations, a hermetic seal may be formed, placed or positioned around the MEMS devices in the shelf region and a non-hermetic seal may be formed, placed or positioned around the MEMS display elements in the display region. In some implementations, the MEMS display elements can include shutter-based light modulators. In some implementations, the smaller substrate can be a transparent cover or cover plate.

Particular implementations of the subject matter described in this disclosure can be implemented to realize one or more of the following potential advantages. Providing MEMS devices in the shelf region of the larger substrate increases the amount of useful area in the display device. That way, space in the shelf region around the IC does not go to waste. In addition, the MEMS devices provided in the shelf region can be formed using some of the same thin film processing steps as the MEMS display elements, which can reduce the overall manufacturing cost. Using a hermetic seal for the MEMS devices in the shelf region and a non-hermetic seal for the MEMS display elements further protects against degradation of the MEMS devices in the shelf region. This increases the lifetime of the display device while preserving a relatively low manufacturing cost. Such packaging can further increase the lifetime of the display device by protecting signal traces against humidity and electrostatic discharge (ESD).

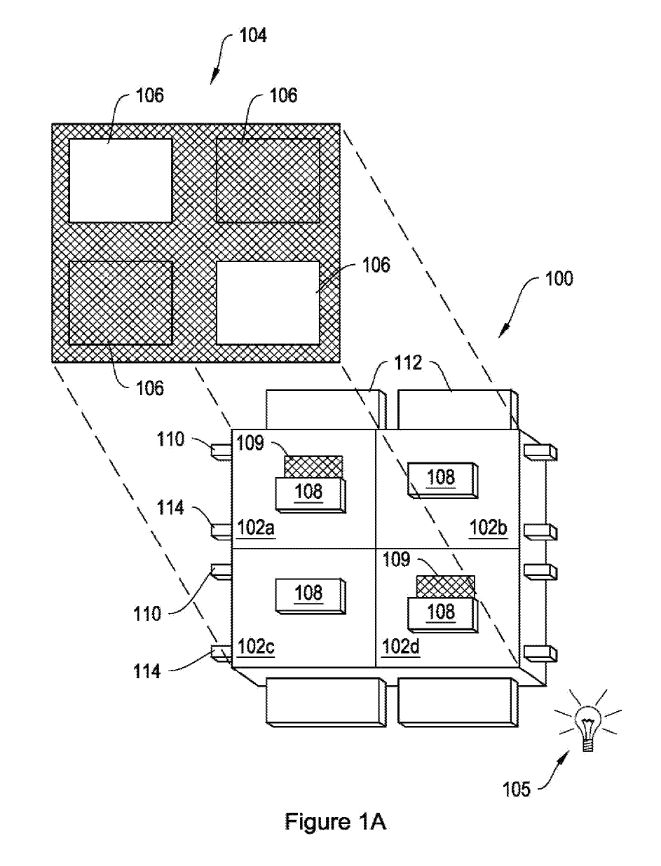

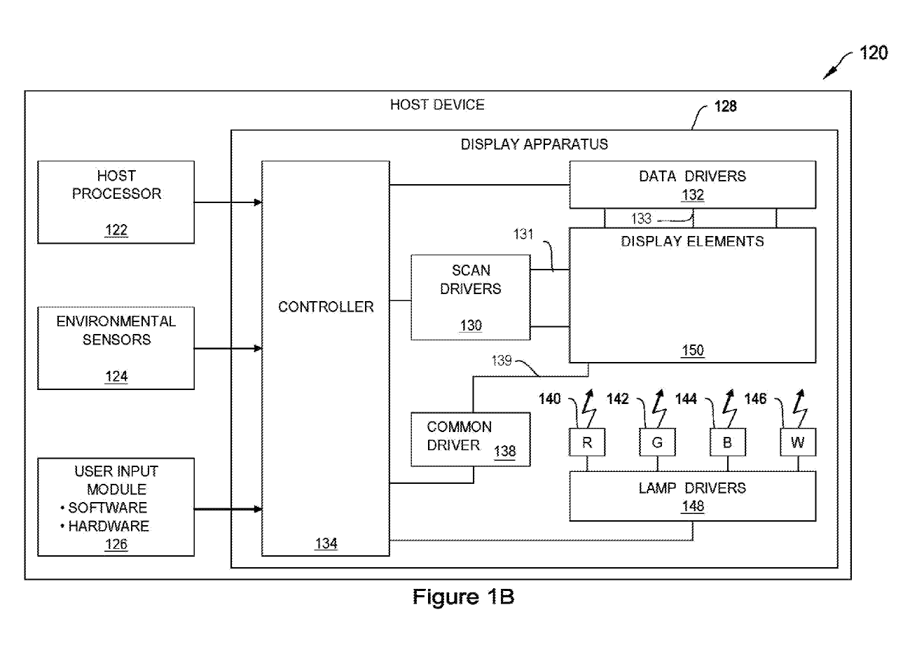

FIG. 1A shows a schematic diagram of an example direct-view MEMS-based display apparatus 100. The display apparatus 100 includes a plurality of light modulators 102a-102d (generally light modulators 102) arranged in rows and columns. In the display apparatus 100, the light modulators 102a and 102d are in the open state, allowing light to pass. The light modulators 102b and 102c are in the closed state, obstructing the passage of light. By selectively setting the states of the light modulators 102a-102d, the display apparatus 100 can be utilized to form an image 104 for a backlit display, if illuminated by a lamp or lamps 105. In another implementation, the apparatus 100 may form an image by reflection of ambient light originating from the front of the apparatus. In another implementation, the apparatus 100 may form an image by reflection of light from a lamp or lamps formed, placed or positioned in the front of the display, i.e., by use of a front light.

In some implementations, each light modulator 102 corresponds to a pixel 106 in the image 104. In some other implementations, the display apparatus 100 may utilize a plurality of light modulators to form a pixel 106 in the image 104. For example, the display apparatus 100 may include three color-specific light modulators 102. By selectively opening one or more of the color-specific light modulators 102 corresponding to a particular pixel 106, the display apparatus 100 can generate a color pixel 106 in the image 104. In another example, the display apparatus 100 includes two or more light modulators 102 per pixel 106 to provide a luminance level in an image 104. With respect to an image, a pixel corresponds to the smallest picture element defined by the resolution of image. With respect to structural components of the display apparatus 100, the term pixel refers to the combined mechanical and electrical components utilized to modulate the light that forms a single pixel of the image.

The display apparatus 100 is a direct-view display in that it may not include imaging optics typically found in projection applications. In a projection display, the image formed on the surface of the display apparatus is projected onto a screen or onto a wall. The display apparatus is substantially smaller than the projected image. In a direct view display, the image can be seen by looking directly at the display apparatus, which contains the light modulators and optionally a backlight or front light for enhancing brightness and/or contrast seen on the display.

Direct-view displays may operate in either a transmissive or reflective mode. In a transmissive display, the light modulators filter or selectively block light which originates from a lamp or lamps formed, placed or positioned behind the display. The light from the lamps is optionally injected into a lightguide or backlight so that each pixel can be uniformly illuminated. Transmissive direct-view displays are often built onto transparent substrates to facilitate a sandwich assembly arrangement where one substrate, containing the light modulators, is formed, placed or positioned over the backlight. In some implementations, the transparent substrate can be a glass substrate (sometimes referred to as a glass plate or panel), or a plastic substrate. The glass substrate may be or include, for example, a borosilicate glass, wine glass, fused silica, a soda lime glass, quartz, artificial quartz, Pyrex, or other suitable glass material.

In FIG. 1, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

Each light modulator 102 can include a shutter 108 and an aperture 109. To illuminate a pixel 106 in the image 104, the shutter 108 is formed, placed or positioned such that it allows light to pass through the aperture 109. To keep a pixel 106 unlit, the shutter 108 is formed, placed or positioned such that it obstructs the passage of light through the aperture 109. The aperture 109 is defined by an opening patterned through a reflective or light-absorbing material in each light modulator 102.

The display apparatus also includes a control matrix coupled to the substrate and to the light modulators for controlling the movement of the shutters. The control matrix includes a series of electrical interconnects (such as interconnects 110, 112 and 114), including at least one write-enable interconnect 110 (also referred to as a scan line interconnect) per row of pixels, one data interconnect 112 for each column of pixels, and one common interconnect 114 providing a common voltage to all pixels, or at least to pixels from both multiple columns and multiples rows in the display apparatus 100. In response to the application of an appropriate voltage (the write-enabling voltage, V_{WE}), the write-enable interconnect 110 for a given row of pixels prepares the pixels in the row to accept new shutter movement instructions. The data interconnects 112 communicate the new movement instructions in the form of data voltage pulses. The data voltage pulses applied to the data interconnects 112, in some implementations, directly contribute to an electrostatic movement of the shutters. In some other implementations, the data voltage pulses control switches, such as transistors or other non-linear circuit elements that control the application of separate drive voltages, which are typically higher in magnitude than the data voltages, to the light modulators 102. The application of these drive voltages results in the electrostatic driven movement of the shutters 108.

The control matrix also may include, without limitation, circuitry, such as a transistor and a capacitor associated with each shutter assembly. In some implementations, the gate of each transistor can be electrically connected to a scan line interconnect. In some implementations, the source of each transistor can be electrically connected to a corresponding data interconnect. In some implementations, the drain of each transistor may be electrically connected in parallel to an electrode of a corresponding capacitor and to an electrode of a corresponding actuator. In some implementations, the other electrode of the capacitor and the actuator associated with each shutter assembly may be connected to a common or ground potential. In some other implementations, the transistor can be replaced with a semiconducting diode, or a metal-insulator-metal switching element.

FIG. 1B shows a block diagram of an example host device 120 (i.e., cell phone, smart phone, PDA, MP3 player, tablet, e-reader, netbook, notebook, watch, wearable device, laptop, television, or other electronic device). The host device 120 includes a display apparatus 128 (such as the display apparatus 100 shown in FIG. 1A), a host processor 122, environmental sensors 124, a user input module 126, and a power source.

The display apparatus 128 includes a plurality of scan drivers 130 (also referred to as write enabling voltage sources), a plurality of data drivers 132 (also referred to as data voltage sources), a controller 134, common drivers 138, lamps 140-146, lamp drivers 148 and an array of display elements 150, such as the light modulators 102 shown in FIG. 1A. The scan drivers 130 apply write enabling voltages to scan line interconnects 131. The data drivers 132 apply data voltages to the data interconnects 133.

In some implementations of the display apparatus, the data drivers 132 are capable of providing analog data voltages to the array of display elements 150, especially where the luminance level of the image is to be derived in analog fashion. In analog operation, the display elements are designed such that when a range of intermediate voltages is applied through the data interconnects 133, there results a range of intermediate illumination states or luminance levels in the resulting image. In some other implementations, the data drivers 132 are capable of applying a reduced set, such as 2, 3 or 4, of digital voltage levels to the data interconnects 133. In implementations in which the display elements are shutter-based light modulators, such as the light modulators 102 shown in FIG. 1A, these voltage levels are designed to set, in digital fashion, an open state, a closed state, or other discrete state to each of the shutters 108. In some implementations, the drivers are capable of switching between analog and digital modes.

The scan drivers 130 and the data drivers 132 are connected to a digital controller circuit 134 (also referred to as the controller 134). The controller 134 sends data to the data drivers 132 in a mostly serial fashion, organized in sequences, which in some implementations may be predetermined, grouped by rows and by image frames. The data drivers 132 can include series-to-parallel data converters, level-shifting, and for some applications digital-to-analog voltage converters.

The display apparatus optionally includes a set of common drivers 138, also referred to as common voltage sources. In some implementations, the common drivers 138 provide a DC common potential to all display elements within the array 150 of display elements, for instance by supplying voltage to a series of common interconnects 139. In some other implementations, the common drivers 138, following commands from the controller 134, issue voltage pulses or signals to the array of display elements 150, for instance global actuation pulses which are capable of driving and/or initiating simultaneous actuation of all display elements in multiple rows and columns of the array.

Each of the drivers (such as scan drivers 130, data drivers 132 and common drivers 138) for different display functions can be time-synchronized by the controller 134. Timing commands from the controller 134 coordinate the illumination of red, green, blue and white lamps (140, 142, 144 and 146 respectively) via lamp drivers 148, the write-enabling and sequencing of specific rows within the array of display elements 150, the output of voltages from the data drivers 132, and the output of voltages that provide for display element actuation. In some implementations, the lamps are light emitting diodes (LEDs).

The controller 134 determines the sequencing or addressing scheme by which each of the display elements can be re-set to the illumination levels appropriate to a new image 104. New images 104 can be set at periodic intervals. For instance, for video displays, color images or frames of video are refreshed at frequencies ranging from 10 to 300 Hertz (Hz). In some implementations, the setting of an image frame to the array of display elements 150 is synchronized with the illumination of the lamps 140, 142, 144 and 146 such that alternate image frames are illuminated with an alternating series of colors, such as red, green, blue and white. The image frames for each respective color are referred to as color subframes. In this method, referred to as the field sequential color method, if the color subframes are alternated at frequencies in excess of 20 Hz, the human visual system (HVS) will average the alternating frame images into the perception of an image having a broad and continuous range of colors. In some other implementations, the lamps can employ primary colors other than red, green, blue and white. In some implementations, fewer than four, or more than four lamps with primary colors can be employed in the display apparatus 128.

In some implementations, where the display apparatus 128 is designed for the digital switching of shutters, such as the shutters 108 shown in FIG. 1A, between open and closed states, the controller 134 forms an image by the method of time division gray scale. In some other implementations, the display apparatus 128 can provide gray scale through the use of multiple display elements per pixel.

In some implementations, the data for an image state is loaded by the controller 134 to the array of display elements 150 by a sequential addressing of individual rows, also referred to as scan lines. For each row or scan line in the sequence, the scan driver 130 applies a write-enable voltage to the write enable interconnect 131 for that row of the array of display elements 150, and subsequently the data driver 132 supplies data voltages, corresponding to desired shutter states, for each column in the selected row of the array. This addressing process can repeat until data has been loaded for all rows in the array of display elements 150. In some implementations, the sequence of selected rows for data loading is linear, proceeding from top to bottom in the array of display elements 150. In some other implementations, the sequence of selected rows is pseudo-randomized, in order to mitigate potential visual artifacts. And in some other implementations, the sequencing is organized by blocks, where, for a block, the data for a certain fraction of the image is loaded to the array of display elements 150. For example, the sequence can be implemented to address every fifth row of the array of the display elements 150 in sequence.

In some implementations, the addressing process for loading image data to the array of display elements 150 is separated in time from the process of actuating the display elements. In such an implementation, the array of display elements 150 may include data memory elements for each display element, and the control matrix may include a global actuation interconnect for carrying trigger signals, from the common driver 138, to initiate simultaneous actuation of the display elements according to data stored in the memory elements.

In some implementations, the array of display elements 150 and the control matrix that controls the display elements may be arranged in configurations other than rectangular rows and columns. For example, the display elements can be arranged in hexagonal arrays or curvilinear rows and columns.

The host processor 122 generally controls the operations of the host device 120. For example, the host processor 122 may be a general or special purpose processor for controlling a portable electronic device. With respect to the display apparatus 128, included within the host device 120, the host processor 122 outputs image data as well as additional data about the host device 120. Such information may include data from environmental sensors 124, such as ambient light or temperature; information about the host device 120, including, for example, an operating mode of the host or the amount of power remaining in the host device's power source; information about the content of the image data; information about the type of image data; and/or instructions for the display apparatus 128 for use in selecting an imaging mode.

In some implementations, the user input module 126 enables the conveyance of personal preferences of a user to the controller 134, either directly, or via the host processor 122. In some implementations, the user input module 126 is controlled by software in which a user inputs personal preferences, for example, color, contrast, power, brightness, content, and other display settings and parameters preferences. In some other implementations, the user input module 126 is controlled by hardware in which a user inputs personal preferences. In some implementations, the user may input these preferences via voice commands, one or more buttons, switches or dials, or with touch-capability. The plurality of data inputs to the controller 134 direct the controller to provide data to the various drivers 130, 132, 138 and 148 which correspond to optimal imaging characteristics.

The environmental sensor module 124 also can be included as part of the host device 120. The environmental sensor module 124 can be capable of receiving data about the ambient environment, such as temperature and or ambient lighting conditions. The sensor module 124 can be programmed, for example, to distinguish whether the device is operating in an indoor or office environment versus an outdoor environment in bright daylight versus an outdoor environment at nighttime. The sensor module 124 communicates this information to the display controller 134, so that the controller 134 can optimize the viewing conditions in response to the ambient environment.

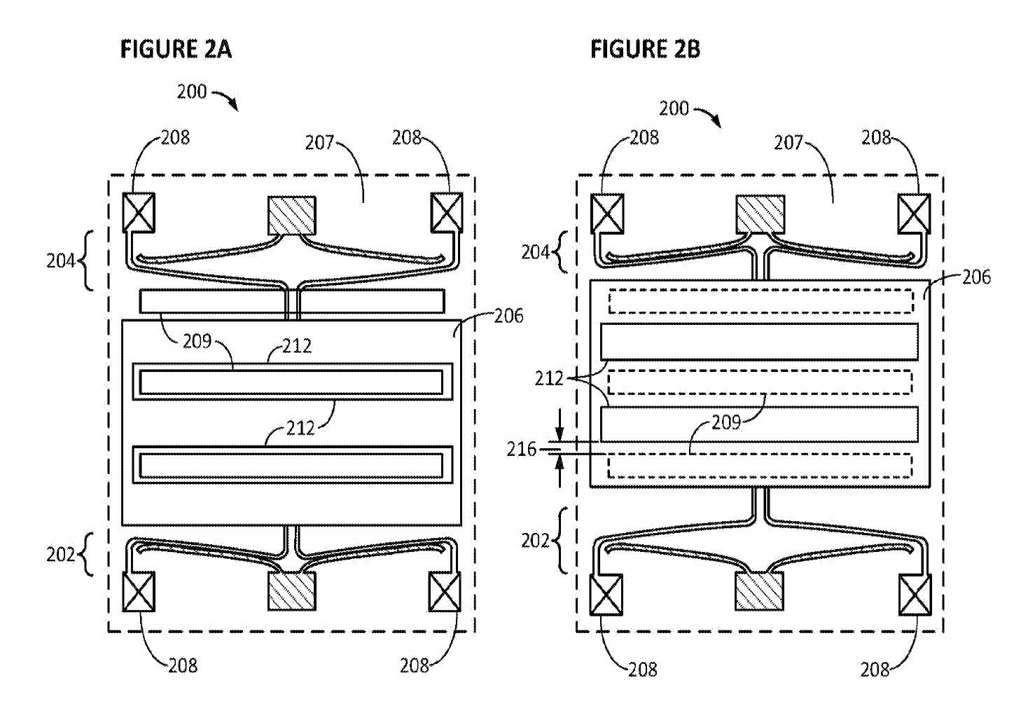

FIGS. 2A and 2B show views of an example dual actuator shutter assembly 200. The dual actuator shutter assembly 200, as depicted in FIG. 2A, is in an open state. FIG. 2B shows the dual actuator shutter assembly 200 in a closed state. The shutter assembly 200 includes actuators 202 and 204 on either side of a shutter 206. Each actuator 202 and 204 is independently controlled. A first actuator, a shutter-open actuator 202, serves to open the shutter 206. A second opposing actuator, the shutter-close actuator 204, serves to close the shutter 206. Each of the actuators 202 and 204 can be implemented as compliant beam electrode actuators. The actuators 202 and 204 open and close the shutter 206 by driving the shutter 206 substantially in a plane parallel to an aperture layer 207 over which the shutter is suspended. The shutter 206 is suspended a short distance over the aperture layer 207 by anchors 208 attached to the actuators 202 and 204. Having the actuators 202 and 204 attach to opposing ends of the shutter 206 along its axis of movement reduces out of plane motion of the shutter 206 and confines the motion substantially to a plane parallel to the substrate (not depicted).

In the depicted implementation, the shutter 206 includes two shutter apertures 212 through which light can pass. The aperture layer 207 includes a set of three apertures 209. In FIG. 2A, the shutter assembly 200 is in the open state and, as such, the shutter-open actuator 202 has been actuated, the shutter-close actuator 204 is in its relaxed position, and the centerlines of the shutter apertures 212 coincide with the centerlines of two of the aperture layer apertures 209. In FIG. 2B, the shutter assembly 200 has been moved to the closed state and, as such, the shutter-open actuator 202 is in its relaxed position, the shutter-close actuator 204 has been actuated, and the light blocking portions of the shutter 206 are now in position to block transmission of light through the apertures 209 (depicted as dotted lines).

Each aperture has at least one edge around its periphery. For example, the rectangular apertures 209 have four edges. In some implementations, in which circular, elliptical, oval, or other curved apertures are formed in the aperture layer 207, each aperture may have a single edge. In some other implementations, the apertures need not be separated or disjointed in the mathematical sense, but instead can be connected. That is to say, while portions or shaped sections of the aperture may maintain a correspondence to each shutter, several of these sections may be connected such that a single continuous perimeter of the aperture is shared by multiple shutters.

In order to allow light with a variety of exit angles to pass through the apertures 212 and 209 in the open state, the width or size of the shutter apertures 212 can be designed to be larger than a corresponding width or size of apertures 209 in the aperture layer 207. In order to effectively block light from escaping in the closed state, the light blocking portions of the shutter 206 can be designed to overlap the edges of the apertures 209. FIG. 2B shows an overlap 216, which in some implementations can be predefined, between the edge of light blocking portions in the shutter 206 and one edge of the aperture 209 formed in the aperture layer 207.

The electrostatic actuators 202 and 204 are designed so that their voltage-displacement behavior provides a bi-stable characteristic to the shutter assembly 200. For each of the shutter-open and shutter-close actuators, there exists a range of voltages below the actuation voltage, which if applied while that actuator is in the closed state (with the shutter being either open or closed), will hold the actuator closed and the shutter in position, even after a drive voltage is applied to the opposing actuator. The minimum voltage needed to maintain a shutter's position against such an opposing force is referred to as a maintenance voltage Vₘ.

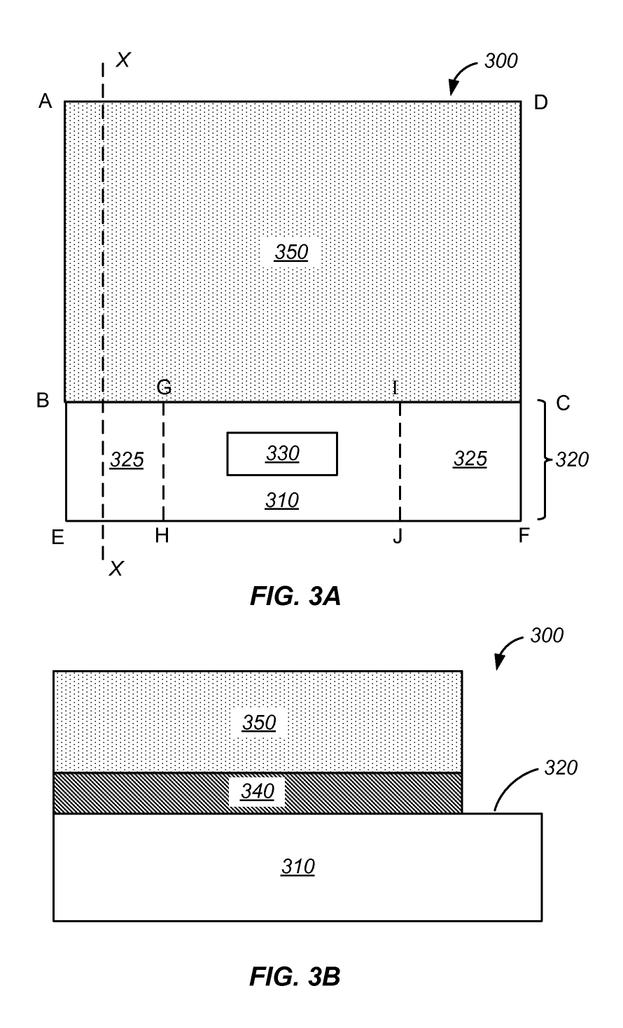

FIG. 3A shows a top view of an example display device 300 indicating unused areas of a substrate 310. FIG. 3B shows a of a cross-sectional side view of the example display device 300 taken along line X-X in FIG. 3A. The display device 300 can have two substrates attached to one another, including a smaller substrate 350 (ABCD) over a larger substrate 310 (AEFD). The larger substrate 310 can serve as a device substrate upon which TFTs and display elements 340 can be formed, placed or positioned. In some implementations, the larger substrate 310 can be referred to as a back plate. In some implementations, the display device 300 can include an active matrix OLED, TFT, IMOD or shutter-based display device.

The larger substrate 310 can be made of any suitable substrate materials, including a substantially transparent material, such as glass or plastic. Substantial transparency as used herein can be defined as transmittance of visible light of about 70% or more, such as about 80% or more or about 90% or more. Glass substrates (sometimes referred to as glass plates or panels) may be or include a borosilicate glass, a soda lime glass, photoglass, quartz, Pyrex or other suitable glass material. A non-glass substrate can be used, such as a polycarbonate, acrylic, polyimide, polyethylene terephthalate (PET) or polyether ether ketone (PEEK) substrate. In some implementations, the larger substrate 310 on which the display elements 340 are fabricated can have dimensions of a few microns to hundreds of microns.

The smaller substrate 350 also can be made of any suitable substrate materials, including a substantially transparent material, such as glass or plastic. Other suitable materials can include the aforementioned materials described with respect to the larger substrate 310. In some implementations, the smaller substrate 350 may be referred to as a cover plate, cover glass, aperture plate or transparent cover. The smaller substrate 350 can be equal to or greater than about 50% of the larger substrate 310, or equal to or greater than about 70% of the larger substrate 310. The smaller substrate 350 can be smaller than the larger substrate 310 so that when the smaller substrate 350 is placed over the larger substrate 310, at least a portion of the larger substrate 310 is not covered. For example, the smaller substrate 350 may have a length or width smaller than the larger substrate 310. Thus, the length or width of the smaller substrate 350 may be equal to or greater than about 50% of the larger substrate 310, or equal to or greater than about 70% of the larger substrate 310. The smaller substrate 350 may provide protection for the display elements 340 from external forces and ambient conditions, such as temperature, pressure, moisture and other environmental conditions.

As illustrated in FIGS. 3A and 3B, the smaller substrate 350 may be smaller than the larger substrate 310 so that a ledge or shelf 320 is exposed. In other words, the smaller substrate 350 may overlap over a portion (ABCD) of the larger substrate 310 but leave another portion (BEFC) of the larger substrate 310 uncovered. The uncovered portion may constitute the shelf 320 of the larger substrate 310. The shelf 320 may extend from one or more sides of the larger substrate 310 that is not covered by the smaller substrate 350. The shelf 320 may include an area in which an IC 330 is provided. However, the shelf 320 may further include unused areas 325 (BEHG and IJFC) in which the IC 330 is not provided. In some implementations, the unused areas 325 may be adjacent to the area of the larger substrate 310 in which the IC 330 is provided.

The larger substrate 310 can include a display region (ABCD) and a shelf region (BEFC). The display region can be a region through which can image can be displayed in the display device 300, and the shelf region can be a non-display region in which an IC can be provided. A plurality of display elements 340 may be formed, placed or positioned in the display region of the larger substrate 310. The display elements 340 may be arranged as an array of display elements, which can be referred to as pixels. Hundreds, thousands or millions of pixels may be arranged in hundreds or thousands of rows and hundreds and thousands of columns. Each of the display elements 340 may be driven by one or more TFTs. In some implementations, the display elements can include MEMS display elements, such as shutter-based display elements. However, while display elements 340 may occupy the display region of the larger substrate 310, the display elements 340 do not occupy the shelf region of the larger substrate 310, thereby leading to a waste of MEMS layers or structures on either side of the IC 330.

The IC 330 attached to the shelf 320 of the larger substrate 310 may be electrically connected to one or more external circuits (not shown). The IC 330 may be electrically connected to external circuits, for example, by a flexible printed circuit board. In addition, the IC 330 may be electrically connected to the display elements 340.

Display devices are increasingly becoming more intelligent by incorporating more and more device components, including touch sensors, pressure sensors, gas sensors, RF switches, accelerometers, gyroscopes, microphones, speakers, etc. Such device components may be integrated in the display device but are formed separately from the display elements. Thus, more processing steps may be needed to form device components in addition to the display elements for a display device. Such processing steps can include deposition, masking and etching steps. Furthermore, the device components may be formed in areas of the display device outside of the shelf where an IC is attached, formed, placed or positioned, resulting in unused areas of the display device.

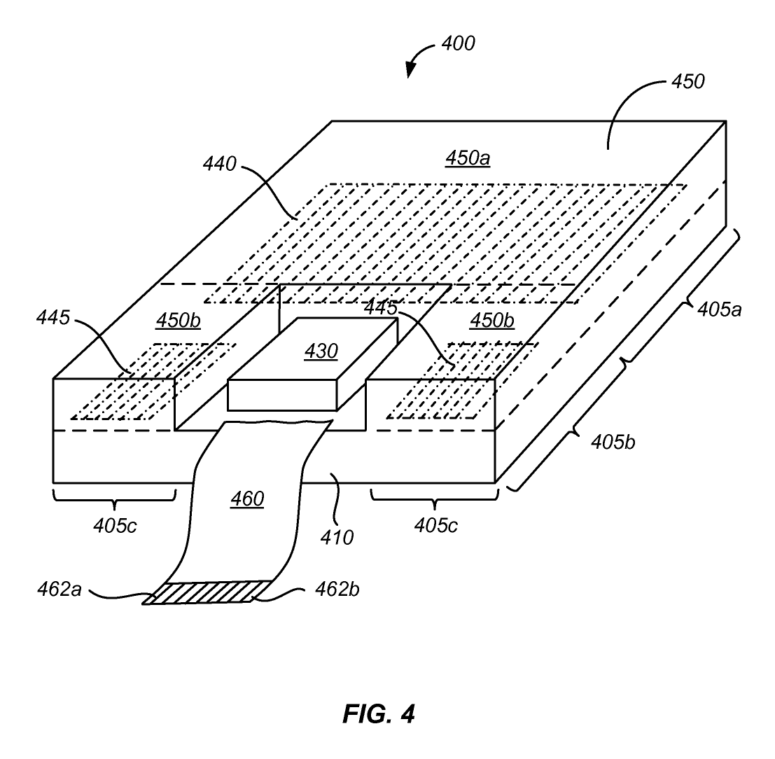

FIG. 4 shows a perspective view of an example display device 400 including a second substrate 450 extending over sensor regions 405c of the display device 400. The display device 400 can include a first substrate 410 and a second substrate 450 over the first substrate 410. The first substrate 410 can have a display region 405a and a shelf region 405b. The shelf region 405b may extend from one or more sides of the display region 405a. The second substrate 450 can be a cover plate or aperture plate covering at least the display region 405a of the first substrate 410. In some implementations, the second substrate 450 can serve as a transparent cover. The second substrate 450 may be provided opposite the first substrate 410. The first substrate 410 may provide a surface upon which various display elements, TFTs and other device components may be built, placed, positioned or formed upon. The second substrate 450 may provide protection for the display elements, TFTs and other device components against external forces and ambient conditions, such as temperature, pressure, moisture and other environmental conditions. In some implementations, the second substrate 450 may be made of the same material as the first substrate 410. For example, the second substrate 450 and the first substrate 410 can each include glass. In some implementations, at least one of the first substrate 410 and the second substrate 450 is transparent. The second substrate 450 and the first substrate 410 may be described with reference to the smaller substrate 350 and the larger substrate 310, respectively, in FIGS. 3A and 3B.

The shelf region 405b may include one or more sensor regions 405c. Sensors or other device components 445 may be incorporated in the sensor regions 405c of the display device 400. Examples of device components 445 include MEMS sensors. The sensor regions 405c may be covered by the second substrate 450. In one or more implementations, additional layers, which may be non-transparent, may be provided over a portion or all of the sensor regions 405c. In some implementations, the second substrate 450 may include a transparent region 450a and a non-transparent region 450b, where the transparent region 450a is over the display region 405a and the non-transparent region 450b is over the sensor regions 405c.

In addition, the display device 400 can include display elements 440 in the display region 405a of the first substrate 410. The display elements 440 can be described with reference to the display elements 340 in FIGS. 3A and 3B. Examples of display elements 440 include MEMS display elements. In some implementations, a display element 440 can include an emissive display element, such as an OLED. In some implementations, a display element 440 can include a reflective display element, such as an IMOD. In some implementations, a display element 440 can include a laterally-movable structure configured to control the transmission of light in the display device 400. For example, the laterally-movable structure can be configured to block transmission of light in the display device 400. Examples of such a display element 440 include a shutter-based display element. In some implementations, the shutter-based display element can be a shutter-based light modulator, which is described with reference to FIGS. 1A-1B and 2A-2B.

The display device 400 can further include an IC 430 formed, placed or positioned in, or on the shelf region 405b of the first substrate 410. The IC 430 may be disposed in a portion of the shelf region 405b that is not covered by the second substrate 450. Specifically, the IC 430 may be disposed in between the sensor regions 405c of the first substrate 410. In some implementations, the IC 430 may be electrically connected to an external circuit 460, such as a flexible printed circuit board. The external circuit 460 may include a plurality of pins 462a and 462b for making electrical connections with various layers and device components. In some implementations, pins 462a and 462b may be electrically connected to MEMS devices or sensors. In some implementations, the IC 430 may be electrically connected with display elements 440 in the display region 405a and the device components 445 in the sensor regions 405c. The electrical interconnections may be made using one or more signal traces (not shown).

The display device 400 may include one or more device components or MEMS devices 445 in the sensor regions 405a of the first substrate 410. The sensor regions 405c may be portions of the shelf region 405b that are covered by the second substrate 450. The one or more MEMS devices 445 can increase functionality of the display device 400. In some implementations, the one or more MEMS devices 445 include one or more MEMS sensors. In some implementations, the one or more MEMS devices 445 include one or more of the following: touch sensors, pressure sensors, gas sensors, RF switches, accelerometers, gyroscopes, microphones and speakers. In some implementations, the one or more MEMS devices 445 can include a cluster of MEMS devices in the sensor regions 405c. The sensor regions 405c may be relatively small in space, but many MEMS devices 445 can be clustered within the space. For example, the sensor regions 405c may be on the order of one or more millimeters square to one or more centimeters square.

The second substrate 450 of the display device 400 may cover the display region 405a and the sensor regions 405c of the first substrate 410. As illustrated in the example in FIG. 4, the second substrate 450 may include arms extending into and over the sensor regions 405c of the first substrate 410. However, the arms of the second substrate 450 do not extend into and over a portion of the shelf region 405b where the IC 430 is attached. The arms of the second substrate 450 also may provide coverage for signal traces that would otherwise be exposed to the ambient environment. Typically, signal traces in the shelf region 405b of the first substrate 410 may be exposed to moisture and ESD damage. However, the second substrate 450 with arms extending over the signal traces in the sensor regions 405c may limit such exposure.

In some implementations, the second substrate 450 including the arms may be integrated as a single body. For example, the second substrate 450 may be a single glass plate. In some implementations, the second substrate 450 may be a combination of discrete components. For example, the arms of the second substrate 450 may include pieces of material or glass separate from the rest of the second substrate 450. In some implementations, some MEMS devices 445 may be packaged differently from other MEMS devices 445 using different materials and seal processes to cover them. Thus, the second substrate 450 may be composed of discrete pieces of material for covering the display region 405a and the sensor regions 405c of the first substrate 410. This allows greater freedom for different seals with respect to the display region 405a and each of the sensor regions 405c. In addition, this permits wider choices of seal processes and different alignment requirements for coupling the first substrate 410 and the second substrate 450 for the display elements 440 in the display region 405a and the MEMS devices 445 in the sensor regions 405c.

Two substrates, such as the first substrate 410 and the second substrate 450, may be attached to one another by a seal disposed between the two substrates. In some implementations, the seal may be provided along a perimeter of the display device 400. In some implementations, different seals may be provided for different regions of the display device 400. A first seal may be disposed around a display region 405a of the first substrate 410 and a second seal may be disposed around sensor regions 405c of the first substrate 410, where the second seal is different than the first seal. The first seal around the display region 405a may be a non-hermetic seal, such as an epoxy seal, and the second seal around the sensor regions 405c may be a hermetic seal, such as a glass frit. Accordingly, each seal may enclose display elements 440 in the display region 405a and MEMS devices 445 in the sensor regions 405c, where the display elements 440 may be enclosed in different environmental conditions than the MEMS devices 445.

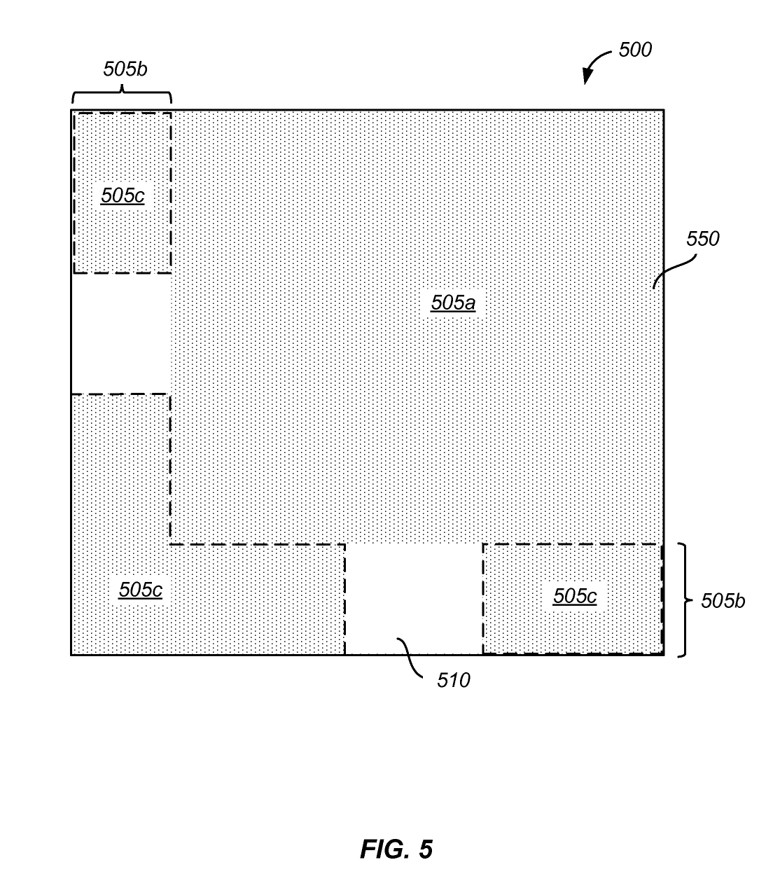

FIG. 5 shows a top view of an example display device 500 including a second substrate 550 with arms extending over two sides of the display device 500. A first substrate 510 may include a display region 505a and a shelf region 505b extending from the left edge of the display region 505a and from the bottom edge of the display region 505a. As used herein, the terms “left edge” and “bottom edge” indicate relative positions corresponding to the orientation of the figure and do not necessarily reflect the actual orientation of the display device as implemented.

Unlike the shelf region 405b in the example in FIG. 4, the shelf region 505b in the example in FIG. 5 extends from the left edge and the bottom edge of the display region 505a. Within the shelf region 505b of FIG. 5, the first substrate 510 also may include sensor regions 505c. In FIG. 5, a second substrate 550 may cover the display region 505a and the sensor regions 505c of the first substrate 510. The second substrate 550 may include arms that extend over the shelf region 505b along the left edge and the bottom edge of the first substrate 510. The arms may be integrated as a single piece with the second substrate 550 in some implementations. Alternatively, the arms may be separate pieces with the second substrate 550. For example, the arms may be discrete pieces of glass over the sensor regions 505c, and the rest of the second substrate 550 may be a discrete piece of glass over the display region 505a. An IC (not shown) may be attached to uncovered portions of the shelf region 505b. The display device 500 in FIG. 5 may permit MEMS devices or MEMS sensors to be formed, placed or positioned in, or on two sides of the first substrate 510, thereby providing device components in addition to display elements to be provided along two sides of the display device 500. In some implementations, the second substrate 550 may be extended over more sides of the first substrate 510, including three sides or four sides of the first substrate 510, to place additional device components along the display device 500. The display device 500 in FIG. 5 may be sealed in the same or similar manner as the display device 400 in FIG. 4.

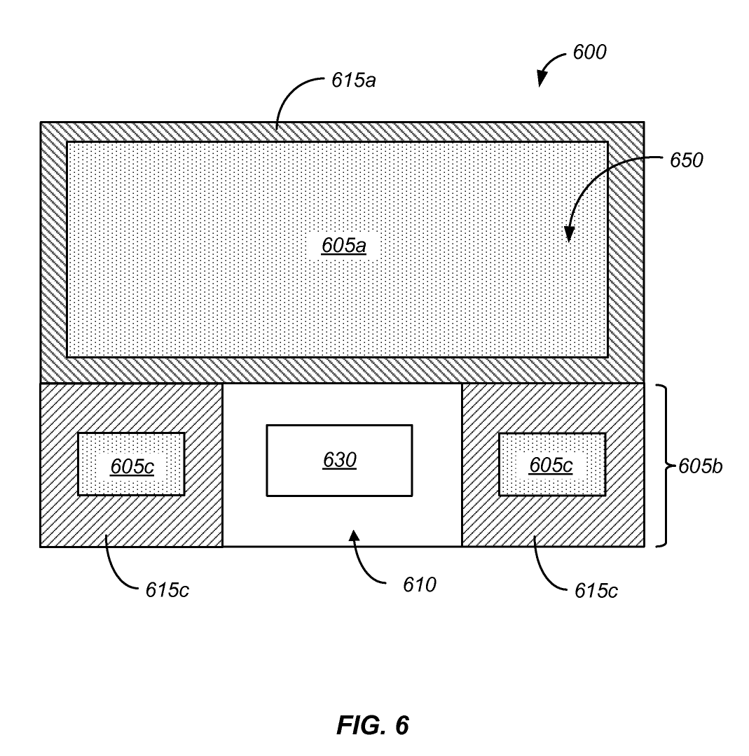

FIG. 6 shows a top view of an example display device 600 with a display region 605a sealed by a non-hermetic seal 615a and sensor regions 605c sealed by a hermetic seal 615c. The display device 600 may be similar to the display device 400 in FIG. 4, with a shelf region 605b extending from a bottom edge of the display region 605a of a first substrate 610 and a second substrate 650 covering the sensor regions 605c of the first substrate 610.

A first seal or a non-hermetic seal 615a may surround a display region 605a of the first substrate 610. The non-hermetic seal 615a may be formed, placed, positioned or otherwise provided to be in contact with the first substrate 610 and the second substrate 650. The non-hermetic seal 615a can include an epoxy-based adhesive that may be dispensed and cured to seal the display region 605a of the display device 600. An epoxy-based adhesive may be curable using a thermal, ultraviolet (UV) or microwave cure. An example of a suitable seal material is a UV-curable epoxy sold by Nagase Chemtex Corporation with a product name XNR5570. The non-hermetic seal 615a may protect MEMS display elements in the display region 605a against moisture ingress.

A second seal or a hermetic seal 615c may surround sensor regions 605c of the first substrate 610. The hermetic seal 615c may be formed, placed, positioned or otherwise provided to be in contact with the first substrate 610 and the second substrate 650. Examples of hermetic seals include metals, welds and glass frits. Methods of hermetic sealing can include metal or solder film preforms, laser or resistive welding techniques and anodic bonding techniques. In some implementations, the hermetic seal 615c is a glass frit. Frit material may be dispensed or printed using screen printing techniques. The first substrate 610 and the second substrate 650 may be aligned. Then the frit material is at least partially melted to form the hermetic seal 615c. The frit material may be heated using a laser or thermal pressing technique. The hermetic seal 615c may prevent ingress of air, water vapor and other environmental contaminants through the seal. In some implementations, MEMS devices (such as MEMS sensors) enclosed by the hermetic seal 615c may be enclosed under certain environmental or atmospheric conditions. Thus, one of the MEMS devices in one of the sensor regions 605c may be enclosed in a first atmosphere and another one of the MEMS devices in another one of the sensor regions 605c may be enclosed in a second atmosphere, where the second atmosphere is different than the first atmosphere. For example, one of the MEMS devices may be enclosed in a vacuum and another one of the MEMS devices may be enclosed with an inert gas.

The display device 600 using a non-hermetic seal 615a for the display region 605a and a hermetic seal 615c for sensor regions 605c can improve the lifetime of the display device 600 without significantly increasing cost. Rather than hermetically sealing the entire display device 600 to limit ingress of moisture, air and other contaminants, specific regions of the display device 600 are hermetically sealed. For example, accelerometers, gyroscopes and other sensors may be hermetically sealed to be enclosed in controlled atmospheric conditions in the sensor regions 605c. However, display elements in the display region 605a may be non-hermetically sealed. Typically, MEMS display elements and MEMS sensors may be sealed using the same sealing materials and processes. However, by sealing MEMS display elements differently than MEMS sensors, the lifetime of the display device 600 may be preserved without significantly increasing cost.

Conventionally, display elements and device components such as sensors are formed at different times using different processing steps. Therefore, the display elements and the device components may be made of different materials and in different layers. However, the MEMS display elements and the MEMS devices of the present disclosure can be made using one or more of the same processing steps. MEMS display elements may include multiple thin film layers and MEMS devices (such as MEMS sensors) also may include multiple thin film layers. The MEMS devices may share two or more of the same thin film layers as the MEMS display elements. Hence, the MEMS display elements and the MEMS sensors may be formed using one or more of the same processing steps, where the processing steps can include deposition, masking and etching steps.

A MEMS display element can be formed, placed or positioned in, or on the display region of the display device and a MEMS device can be formed, placed or positioned in, or on the sensor region of the display device. The MEMS device may share at least some the same materials as the MEMS display element. In some implementations, the MEMS device may share two or more of the same thin film layers as the MEMS display element. Such thin film layers can be formed concurrently. In some implementations, each of the two or more thin film layers shared between the MEMS device and the MEMS display element can have the same composition and thickness.

The MEMS device may be formed simultaneously with the MEMS display element. Hence, the MEMS device can be formed using at least some of the same thin film processing steps as the MEMS display element. In some implementations, the thin film processing steps used in forming the MEMS device may constitute a subset of the thin film processing steps used in forming the MEMS display element. While at least some of the thin film layers for the MEMS device and the MEMS display element may be the same, different design rules may be applied to the MEMS device with respect to the MEMS display element. For example, even though the MEMS device and the MEMS display element share some of the same thin film layers, different masks may be applied to the MEMS device compared to the MEMS display element. Forming the MEMS device simultaneously with the MEMS display element can reduce the overall manufacturing cost of display device. Accordingly, the formation of the MEMS device becomes a byproduct of the formation of the MEMS display element to increase the functionality of the display device.

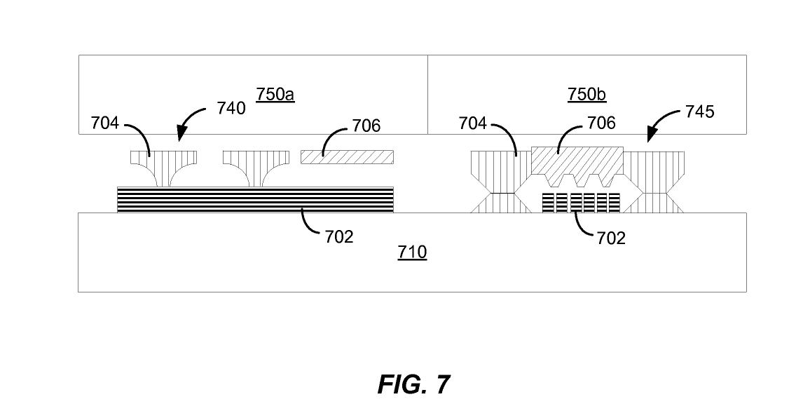

FIG. 7 shows a cross-sectional view of an example of MEMS display element 740 and MEMS device 745 on a first substrate 710. The MEMS display element 740 and the MEMS device 745 may be covered by a second substrate 750 having a first region 750a and a second region 750b. The first region 750a may be over the MEMS display element 740 and the second region 750b may be over the MEMS device 745. In some implementations, the first region 750a may be transparent and the second region 750b may be non-transparent.

The MEMS display element 740 can be made up of a plurality of thin film layers 702, 704 and 706. In some implementations, the MEMS display element 740 is a shutter-based display element. For example, each of the thin film layers 702, 704 and 706 may form part of the shutter-based display element, where a first thin film layer 702 includes an reflective film, a second thin film layer 704 includes an anchor and a third thin film layer 706 includes a shutter. The MEMS display element 740 may share two or more of the same thin film layers as the MEMS device 745. In some implementations, the MEMS display element 740 may be formed using one or more of the same thin film processing steps as the MEMS device 745. The MEMS device 745 can be made up of a plurality of thin film layers include thin film layers 702, 704 and 706. In some implementations, the MEMS device 745 is an accelerometer. For example, each of the thin film layers 702, 704 and 706 may form part of an accelerometer, where the first thin film layer 702 can include metal layers, the second thin film layer 704 can include posts and the third thin film layer can include a proof mass. Hence, the MEMS display element 740 and the MEMS device 745 can be formed, placed or positioned using the same thin film layers 702, 704 and 706. The thin film layers 702, 704 and 706 for both the MEMS display element 740 and the MEMS device 745 are formed using one or more of the same deposition and patterning steps.

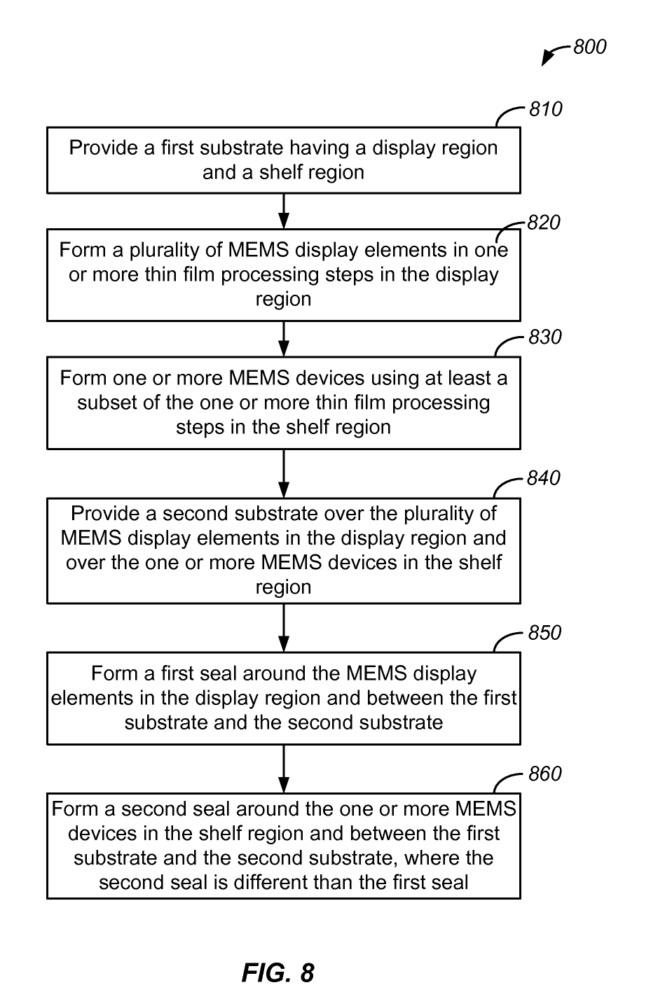

FIG. 8 shows a flow diagram illustrating an example process 800 for manufacturing a display device. The process 800 may be performed in a different order or with different, fewer or additional operations. In some implementations, the process 800 may be described with reference to a MEMS display device.

At block 810 of the process 800, a first substrate is provided. The first substrate can include a display region through which an image can be displayed, and a shelf region extending outside of the display region. The shelf region can serve as ledges extending from one or more sides of the display region. The first substrate can be made of any substrate materials, such as glass or plastic. In some implementations, the first substrate may be referred to as a back plate.

At block 820 of the process 800, a plurality of MEMS display elements are formed in one or more thin film processing steps in the display region. In some implementations, the MEMS display elements can include an active matrix OLED, shutter-based light modulator or IMOD. For example, the MEMS display elements can include shutter-based display elements, such as shutter-based light modulators. Each of the MEMS display elements can include a laterally-movable structure configured to block the transmission of light to the display device. The one or more thin film processing steps can include deposition, masking and/or etching steps in forming the thin film layers of the MEMS display elements. Each of the MEMS display elements can include multiple thin film layers, the thin film layers deposited and patterned in the display region according to certain design rules and masks.

At block 830 of the process 800, one or more MEMS devices are formed in the shelf region using at least a subset of the one or more thin film processing steps. In some implementations, the one or more MEMS devices may include thin film layers that are deposited at the same time as some of the thin film layers of the MEMS display elements. In some implementations, the thin film layers of the one or more MEMS devices may be patterned at the same time as some of the thin film layers of the MEMS display elements, but different masks and design rules may be applied. In some implementations, the thin film layers of the one or more MEMS devices may include thin film layers that are the same as two or more thin film layers of the MEMS display elements.

The one or more MEMS devices may be formed in unused areas of the shelf region. In some implementations, the one or more MEMS devices can include one or more MEMS sensors. In some implementations, the one or more MEMS devices can include one or more touch sensors, pressure sensors, gas sensors, RF switches, accelerometers, gyroscopes, microphones and speakers. The one or more MEMS devices may be formed in portions of the shelf region where an IC is not attached or not configured to be attached. In some implementations, the one or more MEMS devices can include a cluster of MEMS devices in the unused areas of the shelf region. While the one or more MEMS devices may be formed simultaneously with the MEMS display elements, the one or more MEMS devices are not formed in the display region of the display device.

At block 840 of the process 800, a second substrate is provided over the plurality of MEMS display elements in the display region and over the one or more MEMS devices in the shelf region. The second substrate can be a cover glass, a cover plate or an aperture plate. In some implementations, the second substrate can be transparent. The second substrate may be formed of any suitable substrate materials, such as glass or plastic. In some implementations, the second substrate may be smaller than the first substrate. The second substrate may include arms extending over the one or more MEMS devices in the shelf region. However, the arms do not extend over the portions of the shelf region where the IC is attached or configured to be attached. In some implementations, the arms may be discrete pieces of material separate from the rest of the second substrate over the display region. In some implementations, the arms over the one or more MEMS devices in the shelf region may be non-transparent while the rest of the second substrate over the display region may be transparent. In some implementations, the arms may be integrated as a single piece of material with the second substrate over the display region.

In some implementations, the process 800 further includes bonding an IC to the shelf region of the first substrate. The IC can be bonded in an area of the shelf region that is exposed by the second substrate. The IC can be connected to an external circuit. Moreover, the IC can be electrically connected to the one or more MEMS devices and the plurality of MEMS display elements.

At block 850 of the process 800, a first seal is formed around the MEMS display elements in the display region, where the first seal is between the first substrate and the second substrate. In some implementations, the first seal can be continuous and formed around a perimeter of the display region. In some implementations, the first seal can be non-hermetic. For example, forming the first seal can include dispensing an epoxy-based adhesive, aligning the second substrate with the first substrate and then curing the epoxy-based adhesive.

At block 860 of the process 800, a second seal is formed around the one or more MEMS devices in the shelf region, where the second seal is between the first substrate and the second substrate. The second seal is different than the first seal. In some implementations, the second seal can be formed around each portion of the shelf region occupied by MEMS devices. In some implementations, the second seal can be hermetic. For example, forming the second seal can include screen printing a layer of frit material, aligning the second substrate with the first substrate and then at least partially melting the frit material to form a glass frit.

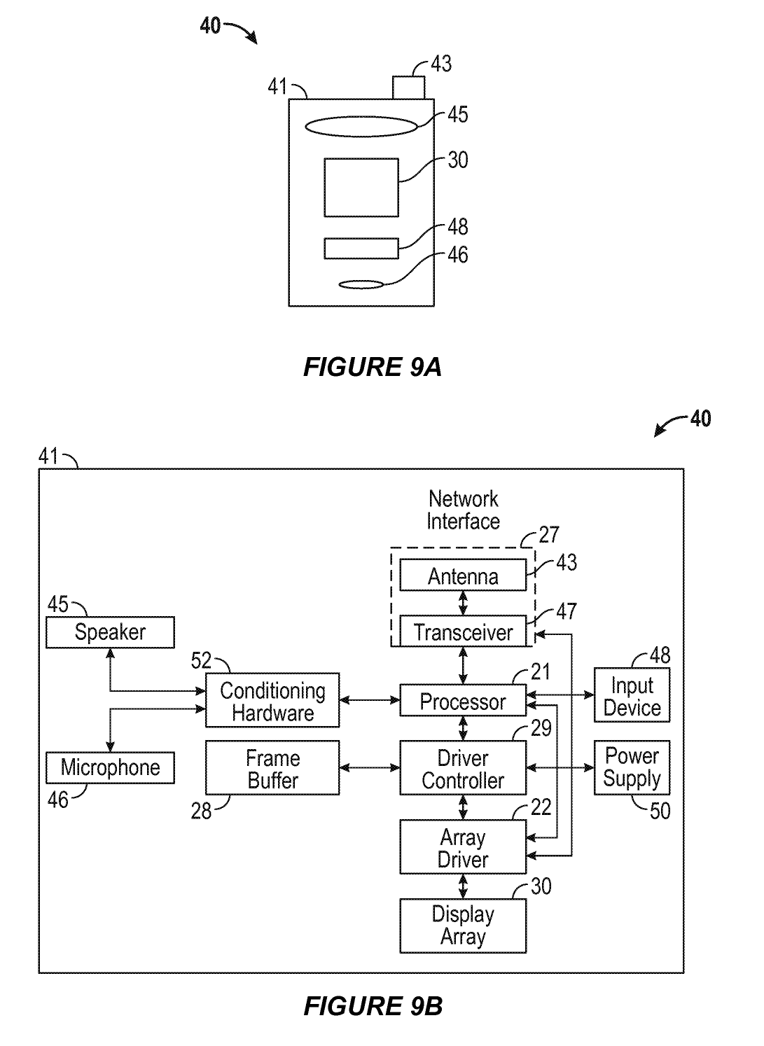

FIGS. 9A and 9B show system block diagrams of an example display device 40 that includes a plurality of display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices. The display device 40 may include non-hermetic seal to seal the MEMS display elements, and a hermetic seal to seal the MEMS devices as described earlier herein.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be capable of including a flat-panel display, such as plasma, electroluminescent (EL) displays, OLED, super twisted nematic (STN) display, LCD, or thin-film transistor (TFT) LCD, or a non-flat-panel display, such as a cathode ray tube (CRT) or other tube device. In addition, the display 30 can include a mechanical light modulator-based display, as described herein.

The components of the display device 40 are schematically illustrated in FIG. 9B. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 9A, can be capable of functioning as a memory device and be capable of communicating with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to any of the IEEE 16.11 standards, or any of the IEEE 802.11 standards. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G, or further implementations thereof, technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29 is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements. In some implementations, the array driver 22 and the display array 30 are a part of a display module. In some implementations, the driver controller 29, the array driver 22, and the display array 30 are a part of the display module.

In some implementations, the driver controller 29, the array driver 22, and the display array 30 are appropriate for any of the types of displays described herein. For example, the driver controller 29 can be a conventional display controller or a bi-stable display controller (such as a mechanical light modulator display element controller). Additionally, the array driver 22 can be a conventional driver or a bi-stable display driver (such as a mechanical light modulator display element controller). Moreover, the display array 30 can be a conventional display array or a bi-stable display array (such as a display including an array of mechanical light modulator display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40. Additionally, in some implementations, voice commands can be used for controlling display parameters and settings.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of any device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A display device, comprising:
a first substrate having a display region and a shelf region;
a plurality of MEMS display elements in the display region, each of the display elements including two or more thin film layers;
one or more MEMS devices in the shelf region, each of the MEMS devices including the same two or more thin film layers;
a second substrate over the plurality of MEMS display elements in the display region and over the one or more MEMS devices in the shelf region;
a first seal around the MEMS display elements in the display region and between the first substrate and the second substrate; and
a second seal around the MEMS devices in the shelf region and between the first substrate and the second substrate, wherein the second seal is different than the first seal.

2. The device of claim 1, further comprising:
an IC in a portion of the shelf region exposed by the second substrate.

3. The device of claim 2, wherein the plurality of MEMS display elements and the one or more MEMS devices are in electrical connection with the IC.

4. The device of claim 1, wherein the MEMS display elements include shutter-based display elements.

5. The device of claim 1, wherein the second substrate has a transparent region and a non-transparent region, the transparent region over the MEMS display elements in the display region and the non-transparent region over the one or more MEMS devices in the shelf region.

6. The device of claim 1, wherein the MEMS display elements include a laterally-movable structure configured to control the transmission of light in the display device.

7. The device of claim 1, wherein the one or more MEMS devices include one or more MEMS sensors.

8. The device of claim 1, wherein the one or more MEMS devices include at least one of a touch sensor, pressure sensor, gas sensor, RF switch, accelerometer, gyroscope, microphone, and speaker.

9. The device of claim 1, wherein the first seal is a non-hermetic seal and the second seal is a hermetic seal.

10. The device of claim 1, wherein the first seal includes an epoxy and the second seal includes a glass frit.

11. The device of claim 1, wherein the second substrate includes arms extending over the one or more MEMS devices in the shelf region.

12. The device of claim 1, wherein the two or more thin film layers of the MEMS display elements share the same composition and thickness as the two or more thin film layers of the one or more MEMS devices.

13. The device of claim 1, further comprising:
a processor capable of communicating with the MEMS display element, the processor being capable of processing image data; and
a memory device capable of communicating with the processor.

14. The device of claim 13, further comprising:
a driver circuit capable of sending at least one signal to the display element; and
a controller capable of sending at least a portion of the image data to the driver circuit.

15. The device of claim 13, further comprising:
an image source module capable of sending the image data to the processor, wherein the image source module includes at least one of a receiver, transceiver, and transmitter.

16. The device of claim 13, further comprising:
an input device capable of receiving input data and communicating the input data to the processor.

17. A display device, comprising:
a first substrate having a display region and a shelf region;
means for displaying an image in the display region, the displaying means including two or more thin film layers, the displaying means including a laterally-movable structure configured to control transmission of light in the display device;
means for sensing in the shelf region, the sensing means including the same two or more thin film layers;
a second substrate over the displaying means in the display region and over the sensing means in the shelf region;
first means for sealing around the displaying means in the display region and between the first substrate and the second substrate; and
second means for sealing around the sensing means in the shelf region and between the first substrate and the second substrate, wherein the second sealing means is different than the first sealing means.

18. The device of claim 17, further comprising:
an IC in a portion of the shelf region exposed by the second substrate.

19. The device of claim 17, wherein the displaying means include shutter-based MEMS light modulators.

20. The device of claim 17, wherein the first sealing means is non-hermetic and the second sealing means is hermetic.

21. The device of claim 17, wherein the second substrate includes arms extending over the sensing means in the shelf region.

22. A method of manufacturing a display device, comprising:
providing a first substrate having a display region and a shelf region;
forming in the display region a plurality of MEMS display elements in one or more thin film processing steps;
forming in the shelf region one or more MEMS devices using at least a subset of the one or more thin film processing steps;
providing a second substrate over the plurality of MEMS display elements in the display region and over the one or more MEMS devices in the shelf region;
forming a first seal around the MEMS display elements in the display region and between the first substrate and the second substrate; and
forming a second seal around the one or more MEMS devices in the shelf region and between the first substrate and the second substrate, wherein the second seal is different than the first seal.

23. The method of claim 22, further comprising:
bonding an IC to a portion of the shelf region exposed by the second substrate.

24. The method of claim 22, wherein MEMS display elements include shutter-based display elements.

25. The method of claim 22, wherein the one or more MEMS devices include one or more MEMS sensors.

26. The method of claim 22, wherein the first seal is a non-hermetic seal and the second seal is a hermetic seal.

27. The method of claim 22, wherein the second substrate includes arms extending over the one or more MEMS devices in the shelf region.

28. The method of claim 22, wherein forming the one or more MEMS devices in the shelf region occurs simultaneously with forming the plurality of MEMS display elements in the display region.
